(19) United States
(12) Patent Application Publication
(10) Pub. No.: US 2006/0049452 A1
(43) Pub. Date: Mar. 9, 2006

(54) Novel LDMOS IC technology with low threshold voltage

(75) Inventors: Ming-Ren Tsai, Sanchung City (TW); Chen-Fu Hsu, Taichung (TW)

Correspondence Address: TUNG & ASSOCIATES, Suite 120, 838 West Long Lake Rd., Bloomfield Hills, MI, 48302, US

(73) Assignee: Taiwan Semiconductor Manufacturing Co., Ltd.

(21) Appl. No.: 10/936,280

(22) Filed: Sep. 7, 2004

(51) Int. Cl. H01L 29/76

(52) U.S. Cl. 257/328

(57) ABSTRACT

A lateral double diffused metal oxide semiconductor (LDMOS) device includes forming a plurality of wells on a semiconductor substrate. The plurality of wells include a first well of a first type, a second well of a second type opposite to the first type, and a third well of the first type. The device includes a gate to control flow from current from a source to a drain. Highly doped regions of the first type provide contacts for the source and the drain. The third well, which is disposed in between the second well, is formed directly below the highly doped region. The third well causes an energy barrier at the source to decrease, thereby resulting in lowering a threshold voltage of the LDMOS device compared to the LDMOS device without the third well.

### BACKGROUND

The present invention relates generally to semiconductor devices and particularly to improving lateral double diffused metal oxide semiconductor (LDMOS) devices.

LDMOS are well known devices, which form an integral part of modern day display panels, telecommunication systems, motor controllers, switch lock power supplies, inverters, and alike, designed for low on-resistance and high blocking voltage. The high voltage (HV) characteristics associated with these applications require that the LDMOS devices have the capacity to withstand voltages, which may vary from about 5V to about 1000V without exhibiting breakdown.

LDMOS devices are field effect transistor (FET) devices which bear a certain resemblance to conventional FET devices insofar as they also include a pair of source/drain regions formed within a semiconductor substrate and separated in part by a channel region also formed within the semiconductor substrate, the channel region in turn having formed thereover a gate electrode. However, LDMOS devices differ from conventional FET devices in part insofar as while a pair of source/drain regions within a FET device is typically fabricated symmetrically with respect to a gate electrode within the FET device, within a LDMOS device a drain region is formed further separated from a gate electrode than a source region, and the drain region is additionally formed within a doped well (of equivalent polarity with the drain region) which separates the drain region from the channel region.

An LDMOS device is basically an asymmetric power MOSFET fabricated using a double diffusion process with coplanar drain and source regions. The low on-resistance and high blocking voltage features of the LDMOS are obtained by creating a diffused P-type channel region in a low-doped N-type drain region. The source and drain regions are on the laterally opposing sides of the gate area. The concentrations of doping are denoted by N− and N+ for n-doped material (n-material), and by P+ and P− for p-doped material (p-material). The low doping on the drain side results in a large depletion layer with high blocking voltage. The channel region diffusion can be defined with the same mask as the source region, resulting in a short channel with high current handling capability. The device may be fabricated by diffusion as well as ion implantation techniques.

A typical structure of an LDMOS device 100, according to the prior art is shown in FIG. 1. N-well of silicon 112 is isolated from P-well 111 by a boundary 113. P-well 111 extends downwards from the top surface and includes N+regions 117 whose distance L 110 from the junction between P-well 111 and N-well 112 defines the channel. The N+regions 117 provide both source 125 and drain 130 contact regions. With the application of positive voltage V_{G} polysilicon gate 116 (beneath which is a layer of gate oxide not explicitly shown), current can flow through the channel from the source 125 into N+ 117, into P-well 111, and into N− well 112 to be collected at N+ 117 by the drain 130. Most LDMOS structures are built on a substrate having one or more other device structures. These devices are isolated by utilizing field oxide (FOX) processes or shallow trench isolation (STI) regions. The role of FOX regions 114 in HV applications is to provide isolation and improve breakdown voltage by reducing electric field density.

Presently, many commercially available HV, e.g., 40V, LDMOS devices have a typical threshold voltage of approximately ±2.8V. However, the typical threshold voltage is often too high for many low voltage devices, which may have driving voltages less than 5V. For example, a 3.3V low voltage (LV) device may not be sufficient to be able to drive the 40V LDMOS device having a typical threshold voltage of approximately ±2.8V. The traditional solution to obtain a lower threshold voltage that is suitable for being driven by a LV device is to add one or more masks during the manufacturing process to adjust the threshold voltage of the HV LDMOS device. Making changes to the manufacturing process, such as the additional masks, generally adds to costs, lengthens cycle time and increases complexity.

Thus, a need exists to provide an improved HV LDMOS device that offers a reduced threshold voltage level that is suitable for being driven by a LV device. In addition, a need exists to manufacture the improved HV LDMOS device without making substantial changes to the manufacturing process.

### SUMMARY OF THE INVENTION

The problems outlined above are addressed in a large part by an apparatus and method for improving LDMOS devices, as described herein. According to one form of the invention, a LDMOS device includes forming plurality of wells on a semiconductor substrate. The plurality of wells include a first well of a first type, a second well of a second type opposite to the first type, and a third well of the first type. The device includes a gate to control flow from current from a source to a drain. Highly doped regions of the first type provide contacts for the source and the drain. The third well, which is disposed in between the second well, is positioned substantially below and abutting the highly doped region. The third well causes an energy barrier at the source to decrease, thereby resulting in lowering a threshold voltage of the LDMOS device compared to the LDMOS device without the third well.

According to another aspect of the invention, the method for reducing the threshold voltage of the LDMOS device includes preparing a plurality of wells on a semiconductor substrate. The plurality of wells include the first, second and third wells. A first highly doped region of the first type is prepared to provide a contact for the source. A second highly doped region of the first type is formed to provide a contact for the drain. A gate is placed between the source and the drain to control a flow of current from the source to the drain. The third well is disposed directly below the first highly doped region. The third well is, thereby, placed in between the second well.

Other forms, as well as objects and advantages of the invention will become apparent upon reading the following detailed description and upon reference to the accompanying drawings.

### BRIEF DESCRIPTION OF THE DRAWINGS

Novel features believed characteristic of the invention are set forth in the appended claims. The invention itself, however, as well as a preferred mode of use, various objectives and advantages thereof, will best be understood by reference to the following detailed description of an illustrative embodiment when read in conjunction with the accompanying drawings.

FIG. 1 is an illustrative cross-sectional diagram of a traditional LDMOS device, described herein above, according to prior art.

FIG. 2 is an illustrative cross-sectional diagram of an improved LDMOS device, according to an embodiment.

FIG. 3 illustrates, in a graphical form, electrical characteristics of a traditional LDMOS device of FIG. 1.

FIG. 4 illustrates, in a graphical form, electrical characteristics of an improved LDMOS device of FIG. 2, according to an embodiment.

FIG. 5 is a flow chart illustrating a method for reducing threshold voltage of an improved LDMOS device of FIG. 2, according to an embodiment.

### DETAILED DESCRIPTION OF AN EMBODIMENT

While the invention is susceptible to various modifications and alternative forms, specific embodiments thereof are shown by way of example in the drawings and will be described herein in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

Elements, which appear in more than one figure herein, are numbered alike in the various figures. The present invention describes an apparatus and method to improve performance of a LDMOS device. According to one form of the invention, a LDMOS device includes forming plurality of wells on a semiconductor substrate. The plurality of wells include a first well of a first type, a second well of a second type opposite to the first type, and a third well of the first type. The device includes a gate to control flow from current from a source to a drain. Highly doped regions of the first type provide contacts for the source and the drain. The third well, which is disposed in between the second well, is positioned substantially below and abutting the highly doped region. The third well causes an energy barrier at the source to decrease, thereby resulting in lowering a threshold voltage of the LDMOS device compared to the LDMOS device without the third well.

FIG. 2 is an illustrative cross-sectional diagram of an improved LDMOS device 200, according to an embodiment. Although the depicted embodiment illustrates the present invention more particularly within the context of a P channel LDMOS device, the present invention is also intended to include an N channel LDMOS device. All remaining semiconductor structures have a complementary polarity to their equivalent structures as illustrated within the depicted embodiment of the present invention.

The LDMOS device 200 includes a source 225, a drain 230 and a gate 216 formed within a plurality of wells. Included in the plurality of wells are a first well 202 of a first type 211, e.g., a N-well 211, a second well 204 of a second type 212 opposite to the first type, e.g., a P-well 212, and a third well 206 of the first type 211, e.g., a N-well 211. Second well 204 of silicon is isolated from the first well 202 by a boundary 213. Similarly, the third well 206 is isolated from the second well 204 by boundaries 218. The second well 204 extends downwards from the top surface and includes a N+region 217 whose distance L 210 from the junction between the boundary 213 defines the channel. The N+regions 217 and 219 provides contact regions for both source 225 and drain 230 respectively. With the application of positive voltage V_{G} polysilicon gate 216 (beneath which is a layer of gate oxide not explicitly shown), current can flow through the channel from the source 225 into N+ 217, into third well 206, into second well 204, into first well 202 to be collected at N+ 219 by the drain 230.

As described earlier, LDMOS structures are built on a substrate having one or more other device structures. These devices are isolated by utilizing FOX regions or shallow trench isolation (STI) regions. The role of FOX regions 209, 214 and 215 in HV applications is to decrease electric field density to improve breakdown voltage. FOX 214 is a first field oxide region disposed between the gate 216 and the drain 230. Approximately one half of the first field oxide 214 is covered by the gate 216. The gate 216 is formed over a first portion 252 of the first well 202 and a channel portion 254 of the second well 204. In one embodiment, the source 225 is coupled to a common ground (GND).

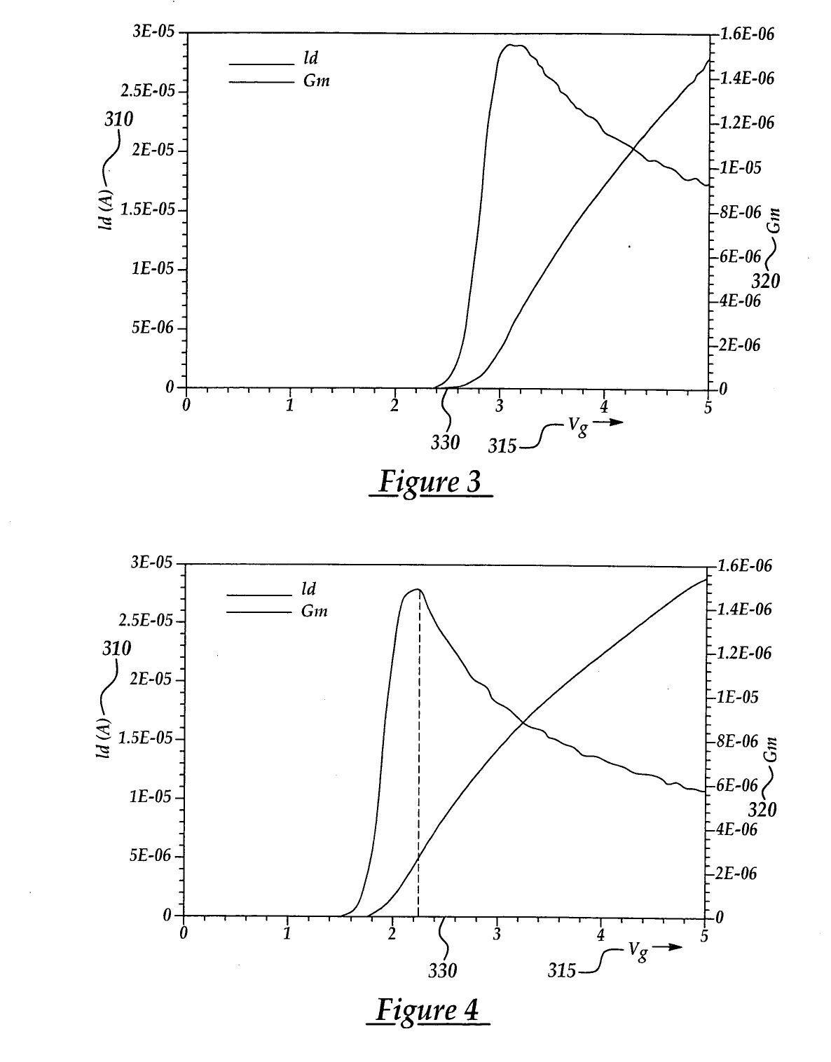

In the depicted embodiment, the LDMOS device 200 includes the third well 206 disposed directly below the N+ 117 source contact region. The boundaries 218 of the third well 206 are substantially aligned with the edges of the N+ 117. Due to the presence of the third well 206 the energy barrier at the source 225 will decrease compared to the LDMOS device 100 without the third well 206. The lowering of the energy barrier, thereby, causes a decrease in a threshold voltage Vₜ (not shown) of the LDMOS device 200. That is, by enhancing a drain induced barrier lowering (DIBL), the threshold voltage Vₜ may be reduced. When the voltage between the drain and source increases, the high potential of the drain will lower the potential barrier and will lead to a reduction in the threshold voltage Vₜ. Additional detail of the electrical characteristics such as Vₜ, a drain current I_{d} and a transconductance gₘ of the LDMOS devices 100 and 200 are described in FIGS. 3 and 4.

In one embodiment, the third well 206 is added during the manufacturing process for the LDMOS device 200, which is substantially similar to the manufacturing process for the LDMOS device 100. Thus the third well 206 is advantageously added without substantially changing the manufacturing process used for manufacturing the LDMOS device 100, which is without the third well 206. That is, no additional masks and/or ion implantation steps need to be added to be able to adjust the threshold voltage Vₜ of the LDMOS device 200. In addition, the third well 206 is advantageously added to adjust threshold voltage Vₜ of the LDMOS device 200 while keeping substantially all the process conditions required for the manufacturing of the LDMOS device 100. This advantageously reduces cost, improves cycle time and results in higher production compared to the threshold voltage Vₜ adjustment process required for the LDMOS device 100.

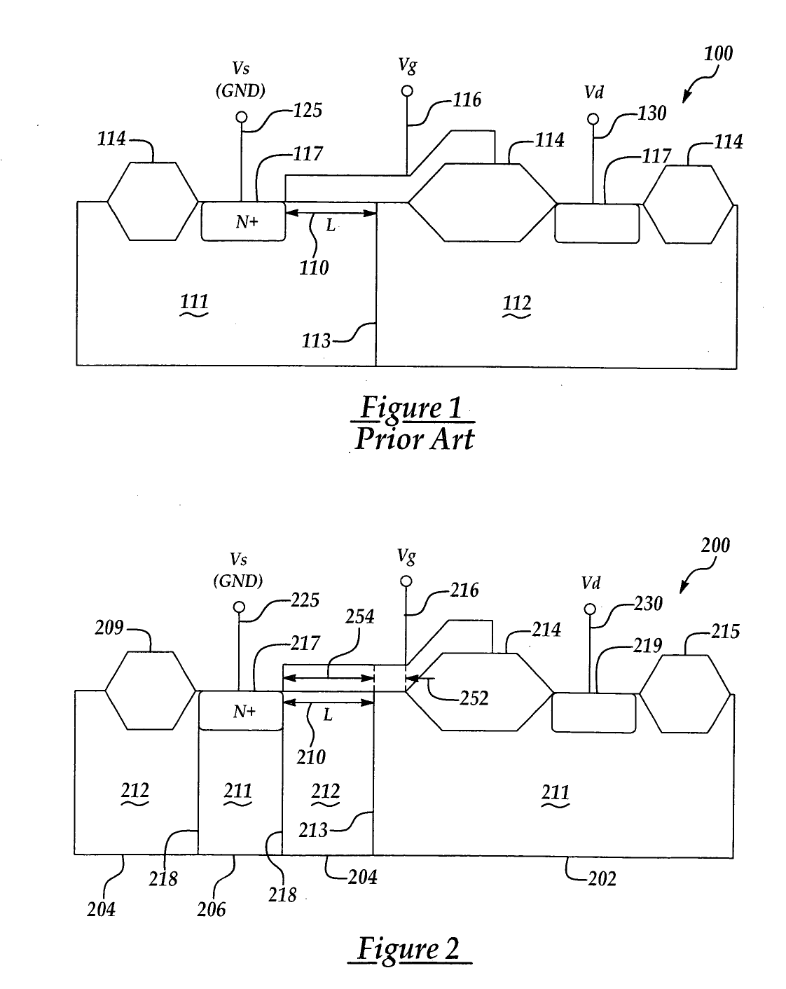

A computer simulation, using a commercially available simulation software program, was performed to illustrate the electrical characteristics of the traditional LDMOS device 100 of FIG. 1 and the electrical characteristics of the improved LDMOS device 200 of FIG. 2.

Shown within FIG. 3 and FIG. 4 are graphical results of the computer simulation, which illustrate the electrical characteristics of the two 40V LDMOS devices. In the depicted embodiment, shown in FIG. 3 is a combined plot of a drain current I_{d} 310 (on Y1 axis) versus gate voltage V_{g} 315 applied to gate 116 (on X axis) and a transconductance gₘ 320 (on Y2 axis) versus gate voltage V_{g} 315 (on X axis) for the LDMOS device 100 of FIG. 1. The transconductance gₘ 320 is defined by an equation 300:
gₘ=(delta I_{d})/(delta V_{g}) Equation 300
where “delta I_{d}” is a difference in the drain current I_{d} 310 caused by a small change “delta V_{g}” in the gate voltage V_{g} 315. The gate voltage V_{g} 315 at which the drain current I_{d} 310 substantially reaches 0 is defined as a threshold voltage Vₜ 330. In the depicted embodiment, a value for threshold voltage Vₜ 330 is approximately 2.72V.

The effect of introduction of the third well 206 (not shown) on the threshold voltage Vₜ 330 is shown in FIG. 4. In the depicted embodiment, shown in FIG. 4 is a combined plot of the drain current I_{d} 310 (on Y1 axis) versus gate voltage V_{g} 315 (on X axis) and the transconductance gₘ 320 (on Y2 axis) versus gate voltage V_{g} 315 (on X axis) for the LDMOS device 200 of FIG. 2. In the depicted embodiment, a value for the threshold voltage Vₜ 330 is approximately 1.71V.

As is illustrated by comparison of the graphs of FIG. 3 and FIG. 4, the threshold voltage 330 is reduced to approximately ±1.7V for the improved LDMOS device 200 in comparison with the approximate ±2.8V corresponding to the LDMOS device 100. This is due to the fact that the energy barrier at the source 225 is advantageously reduced by the addition of the third well 206. Due to a lower value of the threshold voltage 330 for the improved LDMOS device 200, the LV devices can advantageously drive 40V LDMOS devices without having to substantially affect the process conditions during the manufacturing process and/or adding extra steps in the manufacturing process.

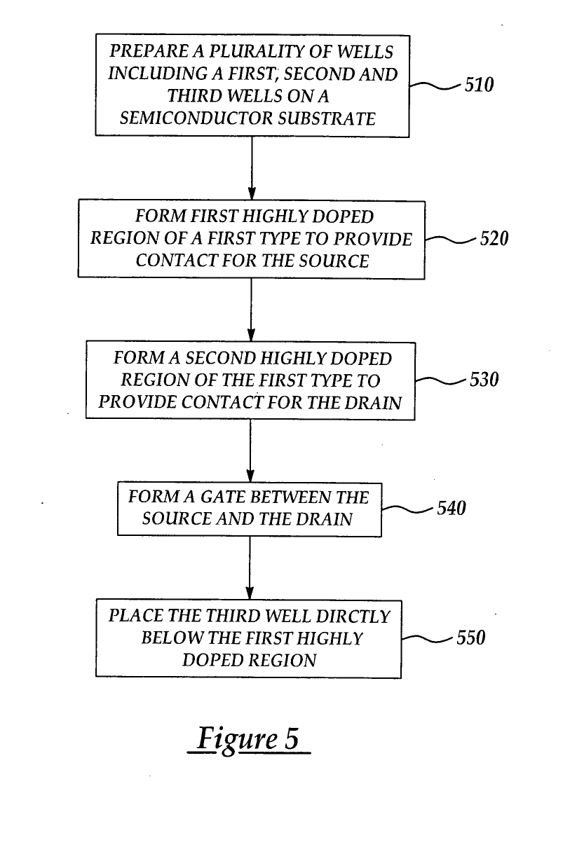

FIG. 5 is a flow chart illustrating a method for reducing the threshold voltage 330 of the LDMOS device 200, according to one embodiment. In step 510, a plurality of wells are prepared on a semiconductor substrate. The plurality of wells include the first, second and third wells 202, 204 and 206 of FIG. 2. In step 520, a first highly doped region of the first type, e.g., N+ 217 is prepared to provide a contact for the source 225. In step 530, a second highly doped region of the first type, e.g., N+ 219, is formed to provide a contact for the drain 230. In step 540, a gate 216 is placed between the source 225 and the drain 230 to control a flow of current from the source 225 to the drain 230. In step 550, the third well 206 is placed directly below the first highly doped region N+ 117. The third well 206 is thereby placed in between the second well 204. Various steps of FIG. 5 may be added, omitted, combined, altered, or performed in different orders.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A metal oxide semiconductor (MOS) device comprising:
a plurality of wells, including a first well of a first type, a second well of a second type opposite to the first type, and a third well of the first type;
a gate to control the LDMOS device;
a drain coupled to the gate formed in the first well;
a source to form a current path with the drain, wherein a highly doped region of the first type provides a contact for the source, wherein the third well is disposed directly below the highly doped region; and
a first field oxide disposed between the gate and the drain, wherein the gate is formed over a first portion of the first well and a channel portion of the second well.

2. The device of claim 1, wherein said MOS device comprises laterally double diffused metal oxide semiconductor (LDMOS) device

3. The device of claim 1, wherein the third well causes an energy barrier at the source to decrease thereby resulting in lowering a threshold voltage of the LDMOS device compared to the LDMOS device without the third well.

4. The device of claim 3, wherein the threshold voltage is lowered from approximately ±2.8V to approximately ±1.7V.

5. The device of claim 1, wherein a first manufacturing process for manufacturing the LDMOS device is substantially similar to a second manufacturing process for manufacturing the LDMOS device without the third well.

6. The device of claim 5, wherein a threshold voltage of the LDMOS device is adjusted without adding an extra mask step to the second manufacturing process.

7. The device of claim 5, wherein a threshold voltage of the LDMOS device is adjusted without adding an extra ion implantation step to the second manufacturing process.

8. The device of claim 5, wherein the first manufacturing process uses a substantially similar mask compared to the second manufacturing process.

9. The device of claim 1, wherein the first well of the first type is a N-well and the second well of the second type is a P-well.

10. The device of claim 1, wherein the LDMOS device is operable to receive high voltages varying from approximately 5V to approximately 1000V.

11. A method for adjusting threshold voltage of a metal oxide semiconductor (LDMOS) device, the method comprising:
preparing a plurality of wells on a semiconductor substrate, the plurality of wells including a first well of a first type, a second well of a second type opposite to the first type, and a third well of the first type;
preparing a first highly doped region of the first type, the first highly doped region being located within the second well to provide a contact for a source of the MOS device;
preparing a second highly doped region of the first type, the second highly doped region being located within the first well to provide a contact for a drain of the MOS device;
placing a gate disposed between the source and the drain for controlling a flow of current from the source to the drain;
placing the third well to be disposed directly below the first highly doped region, the third well being placed in between the second well.

12. The method of claim 11, wherein the placing of the third well causes an energy barrier at the source to decrease thereby resulting in lowering a threshold voltage of the LDMOS device compared to the LDMOS device without the third well.

13. The device of claim 11, wherein said MOS device comprises laterally double diffused metal oxide semiconductor (LDMOS) device

14. The method of claim 12, wherein the threshold voltage is lowered from approximately ±2.8V to approximately ±1.7V.

15. The method of claim 11, wherein a first manufacturing process for manufacturing the LDMOS device is substantially similar to a second manufacturing process for manufacturing the LDMOS device without the third well.

16. The method of claim 11, wherein a threshold voltage of the LDMOS device is adjusted without adding an extra mask step to the second manufacturing process.

17. The method of claim 11, wherein a threshold voltage of the LDMOS device is adjusted without adding an extra ion implantation step to the second manufacturing process.

18. The method of claim 11, wherein the first manufacturing process uses a substantially similar mask compared to the second manufacturing process.

19. The method of claim 11, wherein the first well of the first type is a N-well and the second well of the second type is a P-well.

20. The method of claim 11, wherein the LDMOS device is operable to receive high voltages varying from approximately 5V to approximately 1000V.
